(19) United States
(12) Patent Application Publication
(10) Pub. No.: US 2020/0087777 A1
(43) Pub. Date: Mar. 19, 2020

(54) VAPOR DEPOSITION SOURCE AND VAPOR DEPOSITION APPARATUS, AND METHOD FOR MANUFACTURING VAPOR DEPOSITION FILM

(71) Applicant: Sharp Kabushiki Kaisha, Sakai City, Osaka (JP)

(72) Inventor: Masao NISHIGUCHI, Sakai City (JP)

(21) Appl. No.: 16/472,224

(22) PCT Filed: Sep. 28, 2017
(86) PCT No.: PCT/JP2017/035217

§ 371 Date: Jun. 21, 2019

(51) Int. Cl. C23C 14/24; H01L 51/00; H01L 51/56; H01L 33/00

(52) U.S. Cl. CPC C23C 14/243; H01L 51/0011; H01L 33/005; H01L 51/56; H01L 51/001

(57) ABSTRACT

The vapor deposition source includes a containing unit configured to contain vapor deposition particles and a plurality of nozzles aligned in a line form along an X axis direction, and in the vapor deposition source, the plurality of nozzles at an end portion in the X axis direction of the containing unit protrude in an oblique direction toward the end portion in the X axis direction, arrangement density of nozzles provided at the end portion in the X axis direction of the containing unit is higher than arrangement density of nozzles provided at a center portion of the containing unit, and a line connecting upper end faces of the nozzles adjacent to each other at the end portion in the X axis direction of the containing unit is linearly provided.

### TECHNICAL FIELD

The disclosure relates to a vapor deposition source referred to as a line source or a linear source and a vapor deposition apparatus including the vapor deposition source, and a method for manufacturing a vapor deposition film by using a vapor deposition particle ejecting device.

### BACKGROUND ART

In a flat panel display such as an electroluminescence (EL) display device including a light emitting element, a vacuum vapor deposition technique is commonly used to form a function layer such as a light-emitting layer to be provided between a pair of electrodes and to constitute the light emitting element.

In manufacturing such a display device, in view of display screen enlargement, manufacturing cost saving, and the like, a large-sized mother substrate being a large-area substrate is used in many cases as a film formed substrate. In the case of performing film formation of a vapor deposition film onto such a large-sized film formed substrate, scan vapor deposition is performed. In the scan vapor deposition, a vapor deposition source referred to as a line source or a linear source is used, and vapor deposition is performed while a film formed substrate is scanned by changing a relative position between the film formed substrate and the vapor deposition source. Such a vapor deposition source is provided with a plurality of ejection ports configured to eject vapor deposition particles and aligned in a row in a line form along a direction orthogonal to a scanning direction.

However, to manufacture a display device configured to perform color display, light-emitting layers having different luminescent colors need to be separately patterned for each pixel. Then, to achieve high definition, a Fine Metal Mask (FMM) provided with a mask opening of high precision is used as a vapor deposition mask. The vapor deposition particles ejected from the vapor deposition source are vapor deposited via the mask opening of the vapor deposition mask onto the film formed substrate. Accordingly, a vapor deposition film of a predefined pattern is film formed on the film formed substrate.

However, the vapor deposition particles incident on the mask opening at a shallow angle in an oblique direction cannot reach the film formed substrate through the mask opening. Thus, in a case where the vapor deposition source has a great length in a longitudinal direction, variation occurs in distribution of the vapor deposition particles in the longitudinal direction of the vapor deposition source, and a film thickness of a portion corresponding to a shadow of the vapor deposition mask becomes small to frequently cause a phenomenon referred to as a shadow such as occurrence of pattern blurring and partial missing of pixels.

As a technique for increasing an incident angle on the film formed substrate, there is a known technique in which a plurality of nozzles protruding to the outside are aligned in a line form on one surface of a vapor deposition source, and opening end faces of the nozzles are directed in an outward direction of the vapor deposition source, and thus, the arrangement range of the nozzles is narrowed to increase the incident angle on the film formed substrate (see, for example, PTL 1).

### CITATION LIST

### Patent Literature

PTL 1: JP 2014-77193 A (published on May 10, 2014).

PTL 2: JP 2004-95275 A (published on Mar. 25, 2004)

### SUMMARY

### Technical Problem

However, when the arrangement range of the nozzles is narrowed to increase the incident angle on the film formed substrate as described above, vapor deposition particles incoming from a plurality of directions cause a film thickness of the vapor deposition film being film formed to increase at a portion facing a center portion of the vapor deposition source in the film formed substrate, while causing a film thickness of the vapor deposition film being film formed to decrease at a portion facing each of both end portions of the vapor deposition source in the film formed substrate.

On the other hand, as a technique related to a vapor deposition source provided with a plurality of openings in a line form, in which variation in distribution of a vapor deposition film in a longitudinal direction is avoided without increase in a length in the longitudinal direction of the vapor deposition source, and a uniform vapor deposition film is film formed, for example, PTL 2 discloses a technique in which a pitch of the openings is set to be great in the vicinity of the center of a vapor deposition source, and is set to be small on the end portion side.

However, in a case where the nozzles protruding to the outside as in PTL 1 are provided, and a pitch of the nozzles on the end portion side of the vapor deposition source is set to be small as in PTL 2, the vapor deposition particles ejected from the nozzles on the end portion side collide with the nozzles adjacent to the nozzles on the end portion side to cause disturbance in distribution of the vapor deposition film being film formed. As a result, uniformity of film thickness distribution of the vapor deposition film being film formed reduces, and a mass-production yield deteriorates.

The disclosure has been achieved in view of the problems described above, and an object of the disclosure is to provide a vapor deposition source and a vapor deposition apparatus, and a method for manufacturing a vapor deposition film enabling suppressing occurrence of a shadow and improving uniformity of film thickness distribution.

### Solution to Problem

To achieve the above-described object, a vapor deposition source according to an aspect of the disclosure includes a containing unit configured to contain vapor deposition particles, and a plurality of nozzles configured to eject the vapor deposition particles, wherein the plurality of nozzles are provided being aligned in a line form along a first direction on one surface of the containing unit, and at least a portion of the plurality of nozzles including nozzles provided at an end portion in the first direction of the containing unit protrudes in an oblique direction toward the end portion in the first direction of the containing unit, arrangement density of nozzles provided at the end portion in the first direction of the containing unit is higher than arrangement density of nozzles provided at a center portion of the containing unit, and a first line connecting upper end faces of the nozzles adjacent to each other at the end portion in the first direction of the containing unit is linearly provided.

To achieve the above-described object, a vapor deposition apparatus according to an aspect of the disclosure includes the vapor deposition source according to an aspect of the disclosure, and in the vapor deposition apparatus, in a state where the vapor deposition source and a film formed substrate are disposed to face each other, vapor deposition is performed while at least one of the vapor deposition source and the film formed substrate is caused to move relative to the other along a second direction orthogonal to the first direction.

To achieve the above-described object, a method for manufacturing a vapor deposition film according to an aspect of the disclosure employs a method for manufacturing a vapor deposition film on a film formed substrate, the method including, in a state where the vapor deposition source and the film formed substrate are disposed to face each other, performing vapor deposition while at least one of the vapor deposition source and the film formed substrate is caused to move relative to the other along a second direction orthogonal to the first direction.

### Advantageous Effects of Disclosure

According to an aspect of the disclosure, a vapor deposition source and a vapor deposition apparatus, and a method for manufacturing a vapor deposition film enabling suppressing a shadow and improving uniformity of film thickness distribution.

### BRIEF DESCRIPTION OF DRAWINGS

FIG. 1 is a perspective view illustrating in a partially enlarged manner, an outline configuration of a vapor deposition source according to a first embodiment of the disclosure in conjunction with spread of vapor deposition particles ejected from the vapor deposition source.

FIGS. 2A and 2B are a cross-sectional view illustrating an outline configuration of a main portion of the vapor deposition source according to the first embodiment of the disclosure in conjunction with an example of dimensions of the main portion and a film formed substrate, and a cross-sectional view illustrating an outline configuration of a main portion of a vapor deposition apparatus including the vapor deposition source, respectively, according to the first embodiment of the disclosure.

FIG. 3 is an explanatory view for a film formation method for measuring film thickness distribution.

FIG. 4 is a cross-sectional view illustrating an outline configuration of a main portion of a vapor deposition source used in Comparative Example 1 in conjunction with an example of dimensions of the main portion and a film formed substrate.

FIG. 5 is a graph showing a relationship between a distance in an X axis direction from a coordinate origin in a film formed substrate, assuming that the coordinate origin is a center position of the film formed substrate, and a relative film thickness, assuming that a maximum film thickness of a vapor deposition film being film formed on the film formed substrate is 100%, in Example 1 and Comparative Example 1.

FIG. 6 is a cross-sectional view illustrating in a partially enlarged manner, an outline configuration of a main portion of a vapor deposition source according to a second embodiment of the disclosure in conjunction with spread of vapor deposition particles ejected from the vapor deposition source.

FIG. 7 is a graph showing a relationship between a distance in an X axis direction from a coordinate origin in a film formed substrate, assuming that the coordinate origin is a center position C1 of the film formed substrate, and a relative film thickness, assuming that a maximum film thickness of a vapor deposition film being film formed on the film formed substrate is 100%, in Example 2 and Comparative Example 1.

FIG. 8 is a cross-sectional view illustrating in a partially enlarged manner, an outline configuration of a main portion of a vapor deposition source according to a third embodiment of the disclosure in conjunction with spread of vapor deposition particles ejected from the vapor deposition source.

### DESCRIPTION OF EMBODIMENTS

### First Embodiment

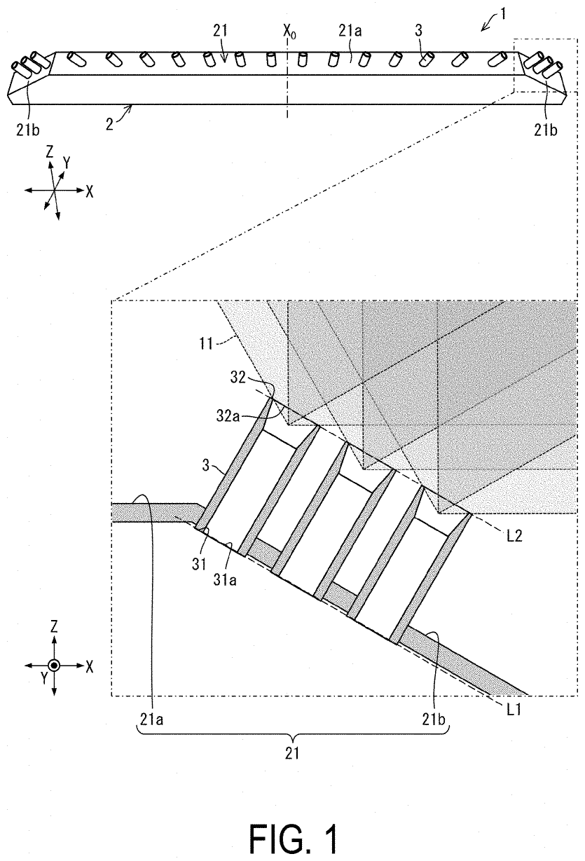

An embodiment of the disclosure will be described below with reference to FIGS. 1 to 5.

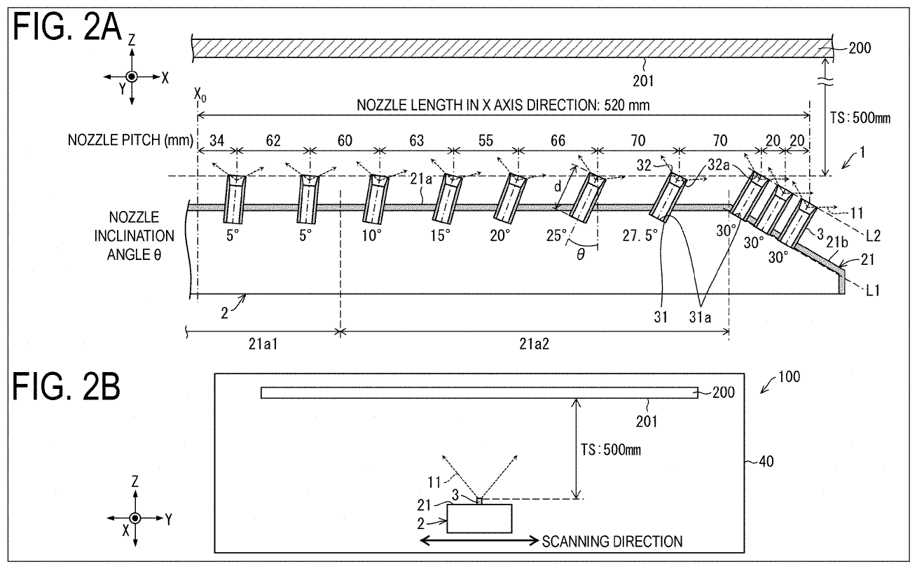

FIG. 1 is a perspective view illustrating in a partially enlarged manner, an outline configuration of a vapor deposition source 1 according to the first embodiment in conjunction with spread of vapor deposition particles ejected from the vapor deposition source 1. FIG. 2A is a cross-sectional view illustrating an outline configuration of a main portion of the vapor deposition source 1 according to the first embodiment in conjunction with an example of dimensions of the main portion and a film formed substrate 200, and FIG. 2B is a cross-sectional view illustrating an outline configuration of a main portion of a vapor deposition apparatus 100 including the vapor deposition source 1 according to the first embodiment.

Hereinafter, description will be given, assuming that a horizontal axis direction being an arrangement direction of nozzles 3 in the vapor deposition source 1 and extending along a direction perpendicular to a scanning direction of the film formed substrate 200 by the vapor deposition source 1 is an X axis direction (first direction), a horizontal axis direction orthogonal to the X axis direction and extending along the scanning direction of the film formed substrate 200 is a Y axis direction (second direction), and a vertical axis (vertical direction axis) direction being a normal direction of a film formed surface 201 of the film formed substrate 200 and perpendicular to an X axis and a Y axis is a Z axis direction. In addition, for the convenience of description, unless otherwise stated, description will be given, assuming that an upward arrow in the Z axis direction indicates the upper side.

As illustrated in FIG. 2B, the vapor deposition apparatus 100 according to the first embodiment is used to film form a vapor deposition film (not illustrated) on the film formed substrate 200.

An example of the film formed substrate 200 described above includes a thin film transistor (TFT) substrate used for an organic EL element mounting substrate in an organic EL display device. An example of the vapor deposition film described above includes an organic film constituting an organic EL element (function film between an anode and a cathode. An example of the organic film includes a light-emitting layer. The vapor deposition apparatus 100 is used, for example, as a manufacturing apparatus of an organic EL display device.

The vapor deposition apparatus 100 includes a vacuum chamber 40, a vapor deposition source 1, a substrate holder (not illustrated) configured to hold the film formed substrate 200, a mask holder (not illustrated) configured to hold a vapor deposition mask (not illustrated), a transport device (not illustrated) configured to vary a relative position between the vapor deposition source 1 and the film formed substrate 200. The vapor deposition source 1, the substrate holder, the mask holder, and the transport device are provided in the vacuum chamber 40. In the vacuum chamber 40, the vapor deposition source 1 is disposed to face the film formed surface 201 of the film formed substrate 200 via a vapor deposition mask (not illustrated).

In the vapor deposition apparatus 100, vapor deposition is performed while the film formed substrate 200 is scanned by moving at least one of the vapor deposition source 1 and the film formed substrate 200 relative to the other by a transport device (not illustrated).

The vapor deposition source 1 is configured to heat and vaporize a vapor deposition material being a film formation material under high vacuum, and to eject the vapor deposition material as vapor deposition particles 11 (evaporating molecules) onto the film formed substrate 200. Accordingly, the vapor deposition particles 11 ejected from the vapor deposition source 1 and having passed through a mask opening provided in the vapor deposition mask are deposited on the film formed surface 201 of the film formed substrate 200, and a vapor deposition film of a predefined pattern is film formed (manufactured). Note that, here, vaporizing a vapor deposition material refers to evaporation of a vapor deposition material when the vapor deposition material is liquid, and refers to sublimation of a vapor deposition material when the vapor deposition material is solid.

The vapor deposition source 1 includes a containing unit 2 configured to contain the vapor deposition particles 11 being a vaporized vapor deposition material and a plurality of nozzles 3 configured to eject the vapor deposition particles 11 in the containing unit 2 to the outside.

The containing unit 2 may be, for example, a container configured to directly contain a vapor deposition material being not vaporized (that is, a vapor deposition material prior to vaporization), or may be a container including a load-lock type pipe, and formed to contain a vapor deposition material being vaporized or not vaporized and supplied from the outside. As an example, the vapor deposition source 1 may include a crucible (not illustrated) being a heat-resistant container configured to contain a vapor deposition material and a heater (heat source) (not illustrated) configured to heat and vaporize the vapor deposition material in the crucible. To prevent clogging of the vapor deposition material, an interior of the containing unit 2 is heated to a temperature not less than a temperature at which the vapor deposition material is vaporized.

The vapor deposition source 1 is a vapor deposition particles ejecting device elongated in a line form (rectangular shape) in a plan view, and referred to as a line source or a linear source. A plurality of the nozzles 3 are provided being aligned in a row in a line form along a direction orthogonal to the scanning direction on one surface of the containing unit 2.

The containing unit 2 is an elongated container of a rectangular pillar-like shape having a length in the X axis direction being the arrangement direction of the nozzles 3 greater than a length in the Y axis direction, and formed in a line form (rectangular shape) in a plan view. As illustrated in FIGS. 2A and 2B, a container having a length in the X axis direction of the containing unit 2 greater than a length in the X axis direction of the film formed substrate 200 and having a length in the Y axis direction of the containing unit 2 smaller than a length in the Y axis direction of the film formed substrate 200 is used for the containing unit 2.

Note that the case where the plurality of nozzles 3 are provided on an upper face 21 of the containing unit 2 will be described below as an example of up-deposition in which the vapor deposition source 1 performs vapor deposition of the vapor deposition particles 11 from the lower side to the upper side. However, the first embodiment is not limited to this case. For example, the nozzles 3 may be provided on a lower face of the containing unit 2. In a case where the nozzles 3 are provided on the lower face of the containing unit 2, the nozzles 3 can be used suitably for down-deposition in which the vapor deposition particles 11 are vapor deposited from the upper side to the lower side.

As illustrated in FIGS. 1 and 2A, assuming that a center position in the X axis direction of the containing unit 2 is a position X₀, the containing unit 2 and the plurality of nozzles 3 are provided line-symmetrically (in other words, bilateral symmetrically) in the X axis direction with the position X₀ being the center.

Both end portions in the X axis direction of the containing unit 2 are each formed in a tapered shape in which a height in the Z axis direction of the containing unit 2 gradually decreases toward the end portion in the X axis direction. Thus, the upper face 21 of the containing unit 2 includes a planar face 21a at a center portion in the X axis direction and includes an inclined face 21b being inclined to be directed outward at each of both the end portions in the X axis direction.

The nozzles 3 are each formed with a cylindrical straight tube having an annular cross section. The nozzles 3 are coupled to the containing unit 2 to communicate with an internal space of the containing unit 2. An opening end face on the lower end side of each of the nozzles 3 coupled to the containing unit 2 is used as a vapor deposition particles inlet 31a. An opening end face on the upper end side of each of the nozzles 3 is used as a vapor deposition particles outlet 32a (ejection port). The center of the opening end face on the upper end side of each of the nozzles 3 is the center of the ejection port. The nozzles 3 each eject, through the vapor deposition particles outlet 32a onto the film formed substrate 200, the vapor deposition particles 11 having entered the nozzle 3 through the vapor deposition particles inlet 31a.

Each nozzle 3 protrudes in an oblique direction from the upper face 21 of the containing unit 2 toward the end portion side in the X axis direction, and includes an upper end face 32 being inclined with respect to a horizontal plane to be directed to the end portion side in the X axis direction of the containing unit 2. Thus, the upper end face 32 of each nozzle 3 is inclined with respect to the film formed surface 201 of the film formed substrate 200. A lower end face 31 and the upper end face 32 of each nozzle 3 are both orthogonal to an axial direction of the nozzle 3. In addition, as described above, these nozzles 3 are provided line-symmetrically in the X axis direction with the position X₀ being the center. Thus, the upper end face 32 of each nozzle 3 is inclined to be directed to the end portion side in the X axis direction more closely located from the position X₀. The upper end faces 32 of the nozzles 3 located equidistant from the position X₀ with the position X₀ being the center are directed in a direction symmetrical with respect to each other.

As illustrated in FIG. 2A, the nozzles 3 provided in a plan view in a central region (hereinafter referred to as a “first region 21a1”) on the planar face 21a of the containing unit 2 are slightly inclined with respect to the normal line direction being an upright direction to each have a nozzle inclination angle θ of, for example, 5 degrees. Here, the nozzle inclination angle θ refers to an angle formed by the axial direction of the nozzle 3 and the normal direction. The nozzle inclination angle θ is appropriately set to make the incident angle of the vapor deposition particles 11 onto the film formed substrate 200 be a desired incident angle.

In the example illustrated in FIG. 2A, for example, each of two nozzles 3 (namely, for example, four nozzles 3 in total) is provided to have the nozzle inclination angle θ of 5 degrees toward each of both the end sides in the X axis direction of the containing unit 2 with the position X₀ being the center. Note that, in FIG. 2A, only a portion between the position X₀ and one end portion in the X axis direction, and the nozzles 3 provided at the portion in the containing unit 2 are illustrated, and illustration of a portion between the position X₀ and the other end portion in the X axis direction, and the nozzles 3 provided at the portion in the containing unit 2 is omitted.

In addition, each nozzle 3 provided in a plan view at a region outside of the first region 21a1 (that is, a region between the first region 21a1 and the inclined face 21b, hereinafter referred to as a “second region 21a2”) on the planar face 21a of the containing unit 2 is designed to have a nozzle inclination angle θ of the nozzle 3 greater than the nozzle inclination angle θ of the nozzle 3 at the first region 21a1 and to gradually increase toward the end portion side in the X axis direction.

Each nozzle 3 provided on the inclined face 21b being a third region on the upper face 21 of the containing unit 2 is designed to have a nozzle inclination angle θ of the nozzle 3 greater than the nozzle inclination angle θ of each of the other nozzles 3 (that is, the nozzles 3 in the first region 21a1 and the second region 21a2). The nozzles 3 provided on the inclined face 21b all have the identical nozzle inclination angle θ. In the example illustrated in FIG. 2A, for example, the nozzle inclination angle θ is set at 30 degrees.

In addition, the nozzles 3 are provided at arrangement density (the number of nozzles per unit area) of the nozzles 3 on the inclined face 21b higher than arrangement density of the nozzles 3 on the planar face 21a. In other words, a pitch in the X axis direction of the nozzles 3 on the inclined face 21b is smaller than a pitch in the X axis direction of the nozzles 3 on the planar face 21a. Here, the pitch in the X axis direction of the nozzles 3 refers to a distance between the centers in the X axis direction of the vapor deposition particles outlets 32a of the nozzles 3 adjacent to each other in the X axis direction.

In the first embodiment, as an example, the pitch in the X axis direction of the nozzles 3 is set as illustrated in FIG. 2A. Thus, a distance (nozzle length in the X axis direction) between the centers in the X axis direction of the vapor deposition particles outlets 32a of the nozzles 3 at both the ends in the X axis direction of the containing unit 2 is set at 1040 mm. That is, as illustrated in FIG. 2A, a distance from the position X₀ to the center in the X axis direction of the vapor deposition particles outlet 32a of the nozzle 3 at each of an outer-most end portions in the X axis direction (nozzle length in the X axis direction from the position X₀) is set at 520 mm. In addition, the pitch in the X axis direction of the nozzles 3 on the inclined face 21b is set at, for example, 20 mm. Note that nozzle diameters of the nozzles 3 are all set identical.

In addition, nozzle lengths d in the axial direction of the nozzles 3 are all set identical. Note that, in the first embodiment, the nozzle length d in the axial direction of the nozzle 3 refers to a distance between the vapor deposition particles inlet 31a and the vapor deposition particles outlet 32a in the axial direction of the nozzle 3. Although not illustrated, in the example illustrated in FIG. 2A, the nozzle length d is set at d=16 mm as an example.

Thus, the vapor deposition source 1 includes, at each of both the end portions in the X axis direction, a nozzle step in a direction indicated by the Z axis direction and connecting the film formed substrate 200 and the vapor deposition source 1. That is, in the first embodiment, the vapor deposition source 1 includes the inclined face 21b at each of both the end portions in the X axis direction of the containing unit 2, and the nozzle 3 having a length identical to the length of the nozzle 3 on the planar face 21a is provided on the inclined face 21b, and thus, a distance (hereinafter referred to as a “TS”) in the Z axis direction between the film formed surface 201 of the film formed substrate 200 and an upper face of the nozzle 3 differs between on the planar face 21a and on the inclined face 21b.

In the first embodiment, the nozzle 3 on the inclined face 21b is provided to include both the lower end face 31 and the upper end face 32 of the nozzle 3 being in parallel with the inclined face 21b. Namely, the nozzles 3 on the inclined face 21b are provided to have a line L1 (second line) connecting the lower end faces 31 of the nozzles 3 adjacent to each other and a line L2 (first line) connecting the upper end faces 32 of the nozzles 3 adjacent to each other on the inclined face 21b, and the lines L1 and L2 are each linearly provided, and are provided to be in parallel with each other and to be in parallel with the inclined face 21b. Note that, in the first embodiment, for example, the inclined face 21b is provided being inclined with respect to the planar face 21a to make the nozzle inclination angle θ be 30 degrees, as described above. The planar face 21a is formed in parallel with the film formed surface 201 of the film formed substrate 200.

### Advantageous Effects

Advantageous effects of the vapor deposition source 1 according to the first embodiment will be described specifically below with reference to measurement results of film thickness distribution according to Examples and Comparative Examples.

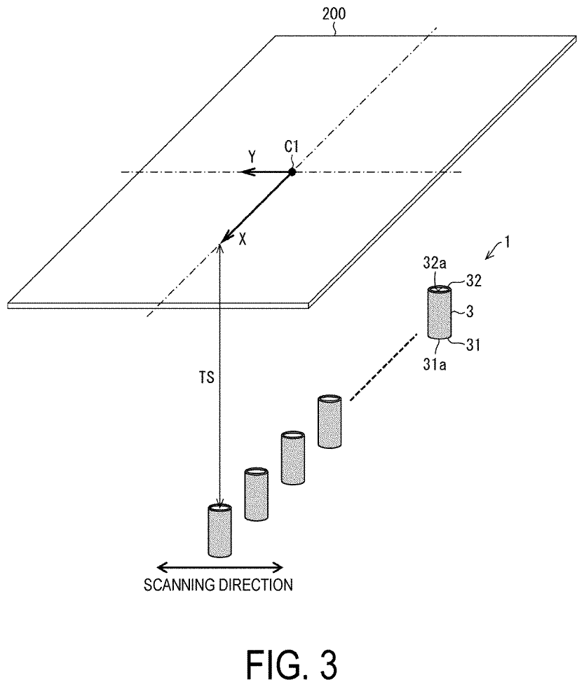

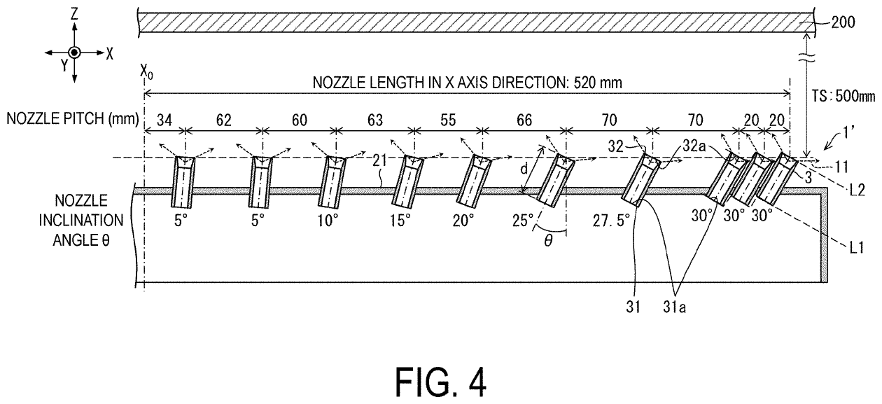

FIG. 3 is an explanatory view for a film formation method for measuring film thickness distribution. In addition, FIG. 4 is a cross-sectional view illustrating an outline configuration of a main portion of a vapor deposition source 1′ used in Comparative Example 1 to be described below in conjunction with an example of dimensions of the main portion and a film formed substrate 200. Note that, in FIG. 4, only a portion between a center position (position X₀) in the X axis direction and one end portion in the X axis direction, and nozzles 3 provided at the portion in a containing unit 2 are illustrated, and illustration of a portion between the position X₀ and the other end portion in the X axis direction, and nozzles 3 provided at the portion in the containing unit 2 is omitted.

The containing unit 2 and a plurality of the nozzles 3 in each of the vapor deposition source 1 and the vapor deposition source 1′ are provided line-symmetrically in the X axis direction with the position X₀ being the center. Then, in the first embodiment, as Example 1, the vapor deposition source 1 and the film formed substrate 200 were disposed facing each other to make a center position in the X axis direction of the film formed substrate 200 coincide with a center position in the X axis direction of the vapor deposition source 1, and film formation (scan vapor deposition) was performed while the film formed substrate 200 is scanned by fixing the film formed substrate 200, and moving, as illustrated in FIG. 3, the vapor deposition source 1 along the Y axis direction.

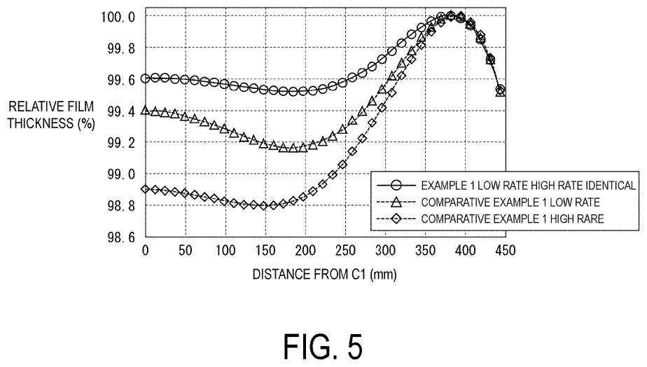

Subsequently, a film thickness of the vapor deposition film being film formed as described above was optically measured at a constant interval along the X axis direction by using a known film thickness measurement apparatus. The results are shown in FIG. 5, and temperature setting and uniformity of film thickness distribution at a high rate at which vapor deposition density is relatively high and at a low rate at which vapor deposition density is relatively low are shown in Table 1.

Note that a pitch in the X axis direction, a nozzle length in the X axis direction, and a nozzle inclination angle θ of each of the nozzles 3 of the vapor deposition source 1 used in measurement as Example 1 were set as illustrated in FIG. 2A. In addition, as illustrated in FIGS. 2A and 2B, a distance TS in the Z axis direction between the film formed surface 201 of the film formed substrate 200 and an upper face of the nozzle 3 was set to make the TS provided on a planar face 21a be 500 mm. A nozzle length d in the axial direction of each nozzle 3 was set at 16 mm as described above. In addition, a nozzle diameter of each nozzle 3 was set constant.

On the other hand, as Comparative Example 1, in place of the vapor deposition source 1, the vapor deposition source 1′ including no inclined face 21b as illustrated in FIG. 4 was used, and film formation of a vapor deposition film was performed in the same manner as in the case of using the vapor deposition source 1, and a film thickness of the vapor deposition film was measured in the same manner as in the case of using the vapor deposition source 1. The results are shown in FIG. 5, and temperature setting and uniformity of film thickness distribution at a high rate and a low rate are shown in Table 1.

Note that a pitch in the X axis direction, a nozzle length in the X axis direction, and a nozzle inclination angle θ of each of the nozzles 3 of the vapor deposition source 1′ used in measurement as Comparative Example 1 were set as illustrated in FIG. 4. In addition, a distance TS in the Z axis direction between a film formed surface 201 of the film formed substrate 200 and an upper face of the nozzle 3 was set at 500 mm in all the containing unit 2. In addition, a nozzle length d in the axial direction of each nozzle 3 was set to be a length identical to the nozzle length d in the axial direction of each nozzle 3 in the vapor deposition source 1. In addition, a nozzle diameter of each nozzle 3 was set to be identical to the nozzle diameter of each nozzle 3 in the vapor deposition source 1.

FIG. 5 is a graph showing a relationship between a distance in the X axis direction from a coordinate origin in the film formed substrate 200, assuming that the coordinate origin is a center position C1 of the film formed substrate 200, and a relative film thickness (measured film thickness/maximum film thickness), assuming that the maximum film thickness of the vapor deposition film being film formed on the film formed substrate 200 is 100%, in Example 1 and Comparative Example 1.

Note that, as described above, the containing unit 2 and the plurality of nozzles 3 in each of the vapor deposition source 1 and the vapor deposition source 1′ are provided line-symmetrically in the X axis direction with the position X₀ being the center. Thus, a relative film thickness of the vapor deposition film is also line-symmetrical in the X axis direction with respect to the center position C1 of the film formed substrate 200. Then, in FIG. 5, film thickness distribution of the vapor deposition film in a direction directed from the center position C1 of the film formed substrate 200, along the X axis direction, to the one end portion in the X axis direction of the film formed substrate 200 is only shown, and film thickness distribution of the vapor deposition film in a direction directed from the center position C1 of the film formed substrate 200, along the X axis direction, to the other end portion in the X axis direction of the film formed substrate 200 is not shown.

In addition, uniformity of the film thickness distribution was calculated from (maximum film thickness−minimum film thickness)/(maximum film thickness+minimum film thickness).

TABLE 1

| | | | Comparative |
|---|---|---|---|
| | | Example 1 | Example 1 |
| Temperature setting | At low rate | 290° C. | 290° C. |
| | At high rate | 300° C. | 300° C. |
| Uniformity of film | At low rate | 0.24% | 0.42% |
| thickness distribution | At high rate | 0.24% | 0.60% |

As illustrated in FIG. 4, in a case where the nozzles 3 each having circular tubular form are inclined with respect to a horizontal plane, at both the end portions in the X axis direction of the containing unit 2 having arrangement density of the nozzles 3 higher than arrangement density of the nozzles 3 at the center portion of the containing unit 2, a line L1 connecting lower end faces 31 of the nozzles 3 adjacent to each other and a line L2 connecting upper end faces 32 of the nozzles 3 adjacent to each other are each provided in zigzag manner.

The vapor deposition source 1 and the vapor deposition source 1′ each include a plurality of the nozzles 3 protruding to the outside in a line form on one surface of the containing unit 2, and these nozzles 3 (more precisely, upper opening end faces of the nozzles 3) are directed in an outward direction of each of the vapor deposition sources 1 and F. Thus, the nozzle length in the X axis direction is made smaller than in the film formed substrate 200, and the incident angle on the film formed substrate 200 is made large. Thus, any of the vapor deposition source 1 and the vapor deposition source 1′ can suppress occurrence of a shadow.

In addition, in any of the vapor deposition source 1 and the vapor deposition source 1′, the arrangement density of the nozzles 3 at the end portion in the X axis direction of the containing unit 2 is higher than the arrangement density of the nozzles 3 at the center portion of the containing unit 2. Thus, variation in the distribution of the vapor deposition film in the X axis direction can be improved without increase in the length in the X axis direction being the longitudinal direction of the containing unit 2.

However, in a case where the line L2 connecting the upper end faces 32 of the nozzles 3 adjacent to each other is provided in a zigzag manner at a portion where the nozzles 3 are densely provided in the containing unit 2 as in the vapor deposition source 1′ described above and the upper end faces 32 of the nozzles 3 adjacent to each other form a step, the vapor deposition particles 11 ejected from the nozzles 3 at the portion collide with the nozzles 3 adjacent (hereinafter referred to as the “adjacent nozzles”) to the nozzles 3 at the portion.

The vapor deposition particles 11 having collided with the adjacent nozzles are heated by the adjacent nozzles to be re-vaporized. As a result, a vapor deposition flow becomes turbulent, and disturbance occurs in the distribution of the vapor deposition film being film formed on the film formed substrate 200. Specifically, as illustrated in FIG. 5 as Comparative Example 1, a film thickness at the end portion in the X axis direction of the film formed substrate 200 varies, and as a result, a film thickness at the center portion of the film formed substrate 200 becomes relatively small. Note that since the end portion in the X axis direction of the film formed substrate 200 is affected by the nozzles 3 densely provided at the end portion in the X axis of the containing unit 2, the film thickness becomes large and the relative film thickness becomes around 100%.

On the other hand, in a case where, as described above, the portion where the nozzles 3 are densely provided includes the inclined face 21b, the line L2 connecting the upper end faces 32 of the nozzles 3 adjacent to each other on the inclined face 21b is linearly provided, and no step is formed between the upper end faces 32 of the nozzles 3 adjacent to each other, the vapor deposition particles 11 ejected from the nozzles 3 at the portion do not collide with the adjacent nozzles as illustrated in FIGS. 1 and 2A. Thus, since interference between a vapor deposition flow of the vapor deposition particles 11 ejected from the nozzles 3 at the above-described portion and a vapor deposition flow of the vapor deposition particles 11 ejected from the adjacent nozzles can be avoided, the distribution of the vapor deposition film being film formed on the film formed substrate 200 is stabilized. Then, as shown in Table 1 as Example 1, uniformity of film thickness distribution becomes identical in the temperature setting at a high rate and the temperature setting at a low rate, and as shown in Table 5 as Example 1, relative film thicknesses are represented by an identical curve at a high rate and a low rate. As a result, even in the case of using a Fine Metal Mask (FMM) provided with a mask opening of high precision as the vapor deposition mask, uniformity and stability of film thickness distribution can be improved, and a mass-production yield can be ensured.

### First Modified Example

Note that in the first embodiment, the case where the nozzles 3 are provided in a row in a line form (that is, on an identical axis) on the upper face 21 of the containing unit 2 is describe as an example. However, the first embodiment is not limited to this case. The nozzles 3 may be provided in multiple rows in a line form.

### Second Modified Example

In addition, in the first embodiment, the case where the vapor deposition film serves as, for example, a function film in an organic EL element (Organic Light-Emitting Diode: OLED) is describe as an example. However, the first embodiment is not limited to this case. The vapor deposition film may serve as, for example, a function film in an inorganic light-emitting diode element (inorganic EL element) or a Quantum-dot Light Emitting Diode (QLED) element. The vapor deposition source 1 may be used generally for film formation (manufacturing) of a vapor deposition film.

The vapor deposition source 1 and the vapor deposition apparatus 100 can be used suitably, for example, as a manufacturing apparatus of an EL display device such as an organic EL display device including an Organic Light-Emitting Diode (OLED) element, and an inorganic EL display device including an inorganic light-emitting diode element, and a QLED display device including a QLED element.

### Second Embodiment

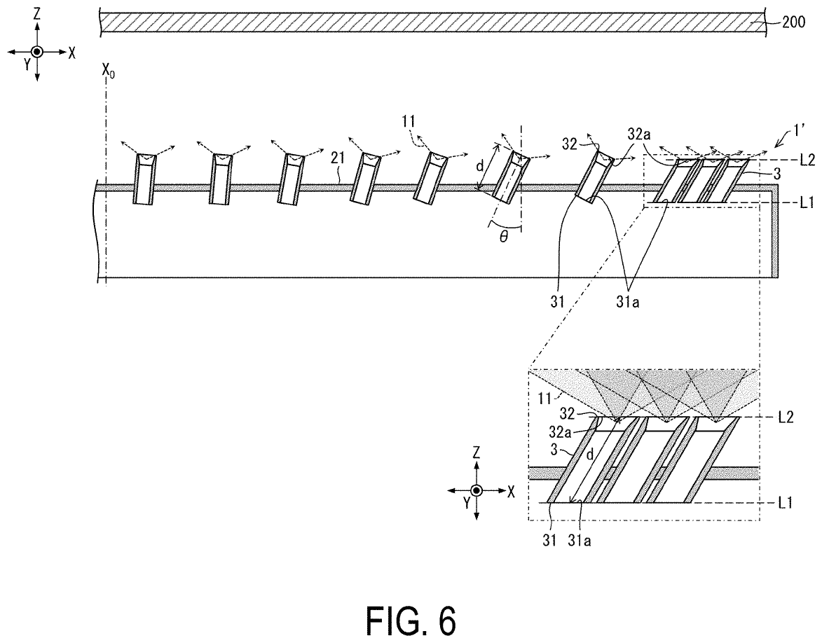

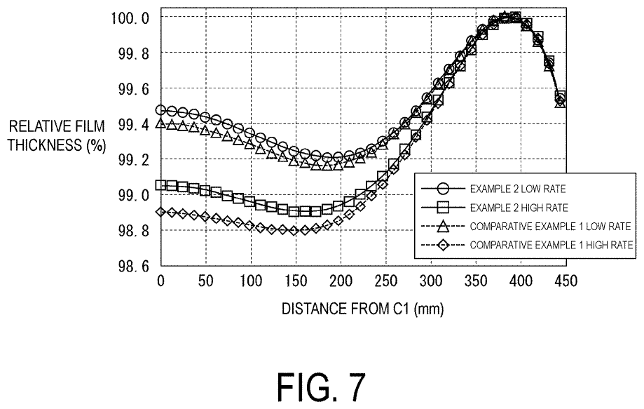

A second embodiment will be described below mainly with reference to FIGS. 6 and 7. Note that in the second embodiment, differences between the second embodiment and the first embodiment will be described, and constituent elements having functions identical to the functions of the constituent elements in the first embodiment are denoted by identical reference signs, and description of such constituent elements will be omitted.

FIG. 6 is a cross-sectional view illustrating in a partially enlarged manner, an outline configuration of a main portion of a vapor deposition source 1 according to the second embodiment in conjunction with spread of vapor deposition particles 11 ejected from the vapor deposition source 1. Note that, similarly, in the second embodiment, a containing unit 2 and a plurality of nozzles 3 in the vapor deposition source 1 are provided line-symmetrically in the X axis direction with a center position (position X₀) in the X axis direction being the center. Thus, similarly, in FIG. 6, only a portion between the position X₀ and one end portion in the X axis direction in the containing unit 2, and the nozzles 3 provided at the portion are illustrated, and illustration of a portion between the position X₀ and the other end portion in the X axis direction, and the nozzles 3 provided at the portion is omitted.

As illustrated in FIG. 6, the vapor deposition source 1 according to the second embodiment includes an upper face 21 of the containing unit 2 being a planar face, and a portion where the nozzles 3 are densely provided at an end portion in the X axis direction of the containing unit 2 includes no inclined face 21b. Thus, the nozzles 3 are all formed on the upper face 21 being a planar face of the containing unit 2.

Alternatively, in the vapor deposition source 1 according to the second embodiment, to avoid formation of a step between upper end faces 32 of the nozzles 3 at the end portion in the X axis direction, the nozzles 3 provided at the end portion in the X axis direction, and obliquely protruding in an oblique direction from the upper face 21 of the containing unit 2 toward the end portion in the X axis direction has a shape formed by being cut at a plane. That is, each of the nozzles 3 at the end portion in the X axis direction has a shape formed by obliquely cutting a cylindrical straight tube to include a lower end face 31 and an upper end face 32 being in parallel with each other and to include an opening end face having an annular elliptical shape. Then, the nozzle 3 at the end portion in the X axis direction is coupled to the containing unit 2 to include the lower end face 31 and the upper end face 32 being horizontal faces (in other words, the lower end face 31 and the upper end face 32 are in parallel with a film formed surface 201 of the film formed substrate 200).

Thus, in the vapor deposition source 1 according to the second embodiment, a line L1 connecting the lower end faces 31 of the nozzles 3 adjacent to each other and a line L2 connecting the upper end faces 32 of the nozzles 3 adjacent to each other at a portion where the nozzles 3 are densely provided at the end portion in the X axis direction are each linearly provided, and the lower end faces 31 and the upper end faces 32 of the nozzles 3 are provided being inclined non-perpendicularly with respect to the axial direction of the nozzles 3 to cause the lines L1 and L2 to be in parallel with each other.

The vapor deposition source 1 according to the second embodiment is identical to the vapor deposition source 1 according to the first embodiment except for the points described above. In addition, the vapor deposition source 1 according to the second embodiment is identical to the vapor deposition source 1′ used for comparison in the first embodiment except that the nozzles 3 at the end portion in the X axis direction are provided to have the lines L1 and L2 each linearly provided and provided in parallel with each other.

### Advantageous Effects

Advantageous effects of the vapor deposition source 1 according to the second embodiment will be described specifically below with reference to measurement results of film thickness distribution according to Examples and Comparative Examples.

In the second embodiment, as a second example, film formation of a vapor deposition film was performed in the same manner as in Example 1 and Comparative Example 1 in the first embodiment by using the vapor deposition source 1 illustrated in FIG. 6, and a film thickness of the vapor deposition film was measured in the same manner as in Example 1 and Comparative Example 1. The results are shown in conjunction with the measurement results for comparison of Comparative Example in the first embodiment in FIG. 7. In addition, temperature setting and uniformity of film thickness distribution at a high rate and a low rate are shown in Table 2.

Note that a pitch in the X axis direction, a nozzle length in the X axis direction, a nozzle inclination angle θ, and a nozzle length d in the axial direction of each nozzle 3 of the vapor deposition source 1 used for the measurement as the second example were set at identical values to in the vapor deposition source 1′ illustrated in FIG. 4. In addition, a distance TS in the Z axis direction between the film formed surface 201 of the film formed substrate 200 and an upper face of the nozzle 3 was set at 500 mm in all the containing unit 2. In addition, a nozzle diameter of each nozzle 3 was set to be identical to the nozzle diameter of each nozzle 3 in the vapor deposition source 1′.

FIG. 7 is a graph showing a relationship between a distance in the X axis direction from a coordinate origin in the film formed substrate 200, assuming that the coordinate origin is a center position C1 of the film formed substrate 200, and a relative film thickness, assuming that a maximum film thickness of the vapor deposition film being film formed on the film formed substrate 200 is 100%, in Example 2 and Comparative Example 1.

Note that similarly, in FIG. 7, for the identical reason as in FIG. 5, film thickness distribution of the vapor deposition film in a direction directed from the center position C1 of the film formed substrate 200, along the X axis direction, to the one end portion in the X axis direction of the film formed substrate 200 is only shown, and film thickness distribution of the vapor deposition film in a direction directed from the center position C1 of the film formed substrate 200, along the X axis direction, to the other end portion in the X axis direction of the film formed substrate 200 is not shown.

TABLE 2

| | | Example 2 |
|---|---|---|
| Temperature setting | At low rate | 290° C. |
| | At high rate | 300° C. |
| Uniformity of film | At low rate | 0.40% |
| thickness distribution | At high rate | 0.55% |

Similarly, in the vapor deposition source 1 according to the second embodiment, as with the vapor deposition source 1 according to the first embodiment, the line L2 connecting the upper end faces 32 of the nozzles 3 adjacent to each other at each of both end portions in the X axis direction of the containing unit 2 where the nozzles 3 are densely provided is linearly provided. Thus, similarly, in the second embodiment, the vapor deposition particles 11 ejected from the nozzles 3 densely provided do not collide with adjacent nozzles as illustrated in FIG. 6. However, in the second embodiment, the upper end face 32 of the nozzle 3 at the end portion in the X axis direction has an annular elliptical shape, and a vapor deposition particles outlet 32a has an elliptical shape, as described above. Thus, a perfect circular shape of the vapor deposition particles outlet 32a is not formed, and directionality of the vapor deposition particles 11 ejected from the nozzles 3 at both the end portions in the X axis direction is unstabilized. Thus, as shown in FIG. 7 and Table 2, uniformity of film thickness distribution is poorer than the uniformity in Example 1, but can be improved as compared to the uniformity in Comparative Example 1, and even in the case of using an FMM, a mass-production yield can be secured more than in the related art.

### Modified Example

As illustrated in FIG. 6, in the second embodiment, the case where the nozzles 3 at the end portion in the X axis direction are provided to have the lines L1 and L2 each linearly provided and provided in parallel with each other is described as an example.

However, in a case where the line L2 is linearly provided, collision with the adjacent nozzles of the vapor deposition particles 11 ejected from the nozzles 3 at the end portion in the X axis direction can be avoided. Thus, the line L1 is not necessarily linearly provided, and for example, only the upper end face 32 of each nozzle 3 at the end portion in the X axis direction in the vapor deposition source 1′ illustrated in FIG. 4 may have a shape formed by being cut at a plane as illustrated in FIG. 6.

However, in this case, as lengths of the nozzles 3 at which variation in the lengths of the nozzles 3 at the end portion in the X axis direction occurs in the X axis direction are smaller, directivity of vapor deposition particles 11 ejected from the nozzle 3 becomes lower. Therefore, when variation in the lengths of the nozzles 3 occurs in the X axis direction, directionality of the vapor deposition particles 11 ejected from the nozzles 3 at both the end portions in the X axis direction becomes unstabilized.

Thus, as illustrated in FIG. 6, the nozzles 3 at the end portion in the X axis direction are further desirably provided to each have a nozzle length d in the axial direction of each nozzle 3 being constant, and to have the lines L1 and L2 each linearly provided and provide in parallel with each other.

### Third Embodiment

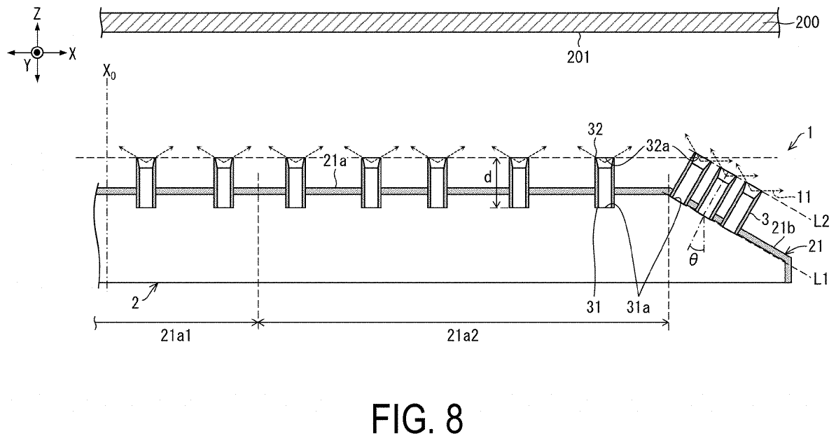

A third embodiment will be described below with reference to FIG. 8. Note that in the third embodiment, differences between the third embodiment and the first and second embodiments will be described, and constituent elements having functions identical to the functions of the constituent element in the first and second embodiments are denoted by identical reference signs, and description of such constituent elements will be omitted.

FIG. 8 is a cross-sectional view illustrating in a partially enlarged manner, an outline configuration of a vapor deposition source 1 according to the third embodiment in conjunction with spread of vapor deposition particles 11 ejected from the vapor deposition source 1. Note that, similarly, in the third embodiment, a containing unit 2 and a plurality of nozzles 3 in the vapor deposition source 1 are provided line-symmetrically in the X axis direction with a center position (position X₀) in the X axis direction being the center. Thus, similarly, in FIG. 8, only a portion between the position X₀ and one end portion in the X axis direction in the containing unit 2, and the nozzles 3 provided at the portion are illustrated, and illustration of a portion between the position X₀ and the other end portion in the X axis direction, and the nozzles 3 provided at the portion is omitted.

The vapor deposition source 1 illustrated in FIG. 8 is identical to the vapor deposition source 1 according to the first embodiment except that the nozzles 3 provided on a planar face 21a and having arrangement density of the nozzles 3 lower than arrangement density of the nozzles 3 on a inclined face 21b at the end portion in the X axis direction on an upper face 21 of the containing unit 2 are provided upright in the Z axis direction, and are not inclined with respect to a film formed substrate 200.

In the vapor deposition source 1, when a line L2 connecting upper end faces 32 of the nozzles 3 provided at the end portion in the X axis direction and having arrangement density of the nozzles 3 being relatively high on a surface facing the film formed substrate 200 of the containing unit 2 is linearly provided, collision with adjacent nozzles of the vapor deposition particles 11 ejected from the nozzles 3 at the end portion in the X axis direction can be avoided.

Therefore, in FIG. 8, the case where the nozzles 3 provided on the planar face 21a are all provided upright in the Z axis direction is illustrated as an example, but a portion of the nozzles 3 provided on the planar face 21a, for example, only some of the nozzles provided with the position X₀ being the center may be provided upright in the containing unit 2.

Thus, the above-described advantageous effects can be obtained even when at least a portion of the nozzles 3 provided at a center portion of the surface facing the film formed substrate 200 of the containing unit 2 and having low arrangement density of the nozzles 3 is provided upright.

Note that, in FIG. 8, the case where the nozzles 3 at the center portion of the containing unit 2 in the vapor deposition source 1 according to the first embodiment are provided upright in the containing unit 2 is illustrated as an example, but the third embodiment is not limited to this case. For example, the same advantageous effects can also be obtained even in a case where at least a portion of the nozzles 3 at the center portion of the containing unit 2 in the vapor deposition source 1 according to the second embodiment is provided upright in the containing unit 2.

### Supplement

A vapor deposition source (1) according to a first aspect of the disclosure includes a containing unit (2) configured to contain vapor deposition particles (11), and a plurality of nozzles (3) configured to eject the vapor deposition particles (11), and in the vapor deposition source (1), the plurality of nozzles are provided being aligned in a line form along a first direction (X axis direction) on one surface (for example, an upper face 21) of the containing unit, and at least a portion of the plurality of nozzles including nozzles provided at an end portion in the first direction (an end portion in the X axis direction) of the containing unit protrudes in an oblique direction toward the end portion in the first direction of the containing unit, arrangement density of nozzles provided at the end portion in the first direction of the containing unit is higher than arrangement density of nozzles provided at a center portion of the containing unit, and a first line (line L2) connecting upper end faces (32) of the nozzles adjacent to each other at the end portion in the first direction of the containing unit is linearly provided.

According to a second aspect of the disclosure, in the vapor deposition source in the first aspect, a second line (line L1) connecting lower end faces (31) of the nozzles adjacent to each other at the end portion in the first direction of the containing unit may be provided linearly, and the first line and the second line may be in parallel with each other.

According to a third aspect of the disclosure, in the vapor deposition source in the first or second aspect, both end portions in the first direction of the containing unit may each include an inclined face (21b) inclined to be directed outward, and on the inclined face, the nozzles may be provided at arrangement density higher than the arrangement density of the nozzles at the center portion of the containing unit.

According to a fourth aspect of the disclosure, in the vapor deposition source in the third aspect, among inclination angles of the plurality of nozzles, inclination angles of nozzles on the inclined face may be greater than inclination angles of other nozzles.

According to a fifth aspect of the disclosure, in the vapor deposition source in the third or fourth aspect, the nozzles on the inclined face may all have an identical inclination angle.

According to a sixth aspect of the disclosure, in the vapor deposition source in any one of the third to fifth aspects, the inclined face may be in parallel with the first line.

According to a seventh aspect of the disclosure, the vapor deposition source in the first or second aspect, the one surface (for example, the upper face 21) of the containing unit may be a planar face and the plurality of nozzles may all be provided on the one surface being a planar face of the containing unit, and the upper end faces of the nozzles provided at the end portion in the first direction of the containing unit may be horizontal faces.

According to an eighth aspect of the disclosure, the vapor deposition source in the seventh aspect, nozzles adjacent to each other at the end portion in the first direction of the containing unit and having the first line linearly provided may all have an identical nozzle inclination angle.

According to a ninth aspect of the disclosure, the vapor deposition source in any one of the first to eighth aspects, the plurality of nozzles may be provided line-symmetrically in the first direction with a center position (position X₀) in the first direction of the containing unit being the center.

A vapor deposition apparatus (100) according to a tenth aspect of the disclosure includes the vapor deposition source according to any one of the first to ninth aspects, and in the vapor deposition apparatus (100), in a state where the vapor deposition source and a film formed substrate (200) are disposed to face each other, vapor deposition is performed while at least one of the vapor deposition source and the film formed substrate is caused to move relative to the other along a second direction (Y axis direction) orthogonal to the first direction.

A method for manufacturing a vapor deposition film according to an eleventh aspect of the disclosure employs a method for manufacturing a vapor deposition film on a film formed substrate (200), the method including, in a state where the vapor deposition source according to any one of the first to ninth aspects and the film formed substrate are disposed to face each other, performing vapor deposition while at least one of the vapor deposition source and the film formed substrate is caused to move relative to the other along a second direction orthogonal to the first direction.

The disclosure is not limited to each of the embodiments described above, and various modifications can be made within the scope of the claims. Embodiments obtained by appropriately combining technical approaches disclosed in the different embodiments also fall within the technical scope of the disclosure. Moreover, novel technical features may be formed by combining the technical approaches stated in each of the embodiments.

### REFERENCE SIGNS LIST

1 Vapor deposition source
2 Containing unit
3 Nozzle
11 Vapor deposition particles
21 Upper face
21a Planar face
21a1 First region
21a2 Second region
21b Inclined face
31 Lower end face
31a Vapor deposition particles inlet
32 Upper end face
32a Vapor deposition particles outlet
100 Vapor deposition apparatus
200 Film formed substrate

1. A vapor deposition source comprising:
a containing unit configured to contain vapor deposition particles; and
a plurality of nozzles configured to eject the vapor deposition particles,
wherein the plurality of nozzles are provided being aligned in a line form along a first direction on one surface of the containing unit, and at least a portion of the plurality of nozzles including nozzles provided at an end portion in the first direction of the containing unit protrudes in an oblique direction toward the end portion in the first direction of the containing unit,
arrangement density of nozzles provided at the end portion in the first direction of the containing unit is higher than arrangement density of nozzles provided at a center portion of the containing unit, and
a first line connecting upper end faces of the nozzles adjacent to each other at the end portion in the first direction of the containing unit is linearly provided.

2. The vapor deposition source according to claim 1,
wherein a second line connecting lower end faces of the nozzles adjacent to each other at the end portion in the first direction of the containing unit is linearly provided, and
the first line and the second line are in parallel with each other.

3. The vapor deposition source according to claim 1,
wherein both end portions in the first direction of the containing unit each include an inclined face inclined to be directed outward, and
on the inclined face, the nozzles are provided at arrangement density higher than the arrangement density of the nozzles at the center portion of the containing unit.

4. The vapor deposition source according to claim 3,
wherein among inclination angles of the plurality of nozzles, inclination angles of nozzles on the inclined face are greater than inclination angles of other nozzles.

5. The vapor deposition source according to claim 3,
wherein the nozzles on the inclined face all have an identical inclination angle.

6. The vapor deposition source according to claim 3,
wherein the inclined face is in parallel with the first line.

7. The vapor deposition source according to claim 1,
wherein the one surface of the containing unit is a planar face and the plurality of nozzles are all provided on the one surface being the planer face of the containing unit, and
the upper end faces of the nozzles provided at the end portion in the first direction of the containing unit are horizontal faces.

8. The vapor deposition source according to claim 7,
wherein nozzles adjacent to each other at the end portion in the first direction of the containing unit and having the first line linearly provided all have an identical nozzle inclination angle.

9. The vapor deposition source according to claim 1,
wherein the plurality of nozzles are provided line-symmetrically in the first direction with a center position in the first direction of the containing unit being the center.

10. A vapor deposition apparatus including the vapor deposition source according to claim 1,
wherein, in a state where the vapor deposition source and a film formed substrate are disposed to face each other, vapor deposition is performed while at least one of the vapor deposition source and the film formed substrate is caused to move relative to the other along a second direction orthogonal to the first direction.

11. A method for manufacturing a vapor deposition film on a film formed substrate, the method comprising:
in a state where the vapor deposition source according to claim 1 and the film formed substrate are disposed to face each other, performing vapor deposition while at least one of the vapor deposition source and the film formed substrate is caused to move relative to the other along a second direction orthogonal to the first direction.
